(19) United States
(12) Patent Application Publication
(10) Pub. No.: US 2006/0044045 A1
(43) Pub. Date: Mar. 2, 2006

(54) Semiconductor apparatus provided with power switching semiconductor device

(75) Inventors: Hiroshi Sakata, Tokyo (JP); Tomofumi Tanaka, Tokyo (JP)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Mitsubishi Denki Kabushiki Kaisha, Tokyo (JP)

(21) Appl. No.: 11/078,501

(22) Filed: Mar. 14, 2005

(30) Foreign Application Priority Data
Aug. 25, 2004 (JP) 2004-245052

(51) Int. Cl. H03K 17/687

(52) U.S. Cl. 327/434

(57) ABSTRACT

A semiconductor apparatus is provided with a power switching semiconductor device, a control integrated circuit, a current detector section, and a protection circuit. The control integrated circuit drives the power switching semiconductor device, and the current detector section detects a current flowing in the power switching semiconductor device. The protection circuit compares a detected voltage obtained from the current detector section with a comparison reference voltage obtained from a predetermined reference voltage, and stops the control integrated circuit from driving the power switching semiconductor device when the detected voltage is higher than the comparison reference voltage. A terminal is further provided that pulls out a line of the comparison reference voltage to an external circuit of the semiconductor apparatus so as to change the comparison reference voltage by means of an external resistor connected to the terminal.

### BACKGROUND OF THE INVENTION

1. Field of the Invention

The present invention relates to a semiconductor apparatus, and in particular, to a semiconductor apparatus including a power switching semiconductor device and a control integrated circuit for driving the power switching semiconductor device.

2. Description of the Related Art

If the semiconductor apparatus is a three-phase output type inverter module, the semiconductor apparatus includes six IGBTs (Insulated-Gate Bipolar Transistors) of power switching semiconductor devices which constitute a three-phase bridge circuit, and three control integrated circuits provided at respective three phases so as to drive these IGBTs. For the purpose of protecting the semiconductor apparatus against an over-current, currents flowing in the IGBT at respective phases are detected by a shunt resistor connected to an external circuit of this semiconductor apparatus, and a voltage detected by the shunt resistor is inputted into one of the control integrated circuits. A comparator included in the control integrated circuit compares the detected voltage with a reference voltage generated by a reference resistor. When the detected voltage is equal to or higher than the reference voltage, then it is judged that the IGBT is in an over-current state, a driving signal is shut off from the control integrated circuit, and the IGBT is turned off.

As can be seen, a trip level for the over-current protection is conventionally set based on a resistance value of the shunt resistor. Generally speaking, the resistance value of the shunt resistor is fixedly set so that the trip for the over-current protection operates when the voltage detected by the shunt resistor is higher than 0.5 V.

There is the following trade-off relationship. If the resistance value is set to be larger, a heat loss at the shunt resistor is higher. On other hand, if the resistance value is set to be smaller, it is difficult to determine the trip level in the control integrated circuit, and the precision of the trip level is reduced. However, conventionally, because of the fixed resistance value of the shunt resistor, it is disadvantageously impossible to select to which a higher priority is given, either a reduction in the heat loss or improvement in the precision of the over-current protection depending on the use state of semiconductor apparatus.

In order to solve above-mentioned problems, the Japanese Patent Laid-Open Publication No. 2001-168652 (referred to as a first patent document hereinafter), for example, discloses a semiconductor apparatus that employs a current mirror circuit that generate a reference voltage at the reference resistor, and that enables a current flowing to the current mirror circuit to be adjusted by a resistor connected to the external circuit of the semiconductor apparatus.

Further, the Japanese Patent Laid-Open Publication No. 2003-319552 (referred to as a second patent document hereinafter) discloses an over-current protection apparatus constituted so that a detected voltage is amplified by an amplifier, the amplified voltage is divided by voltage-dividing resistors, and a resultant voltage is compared with a reference voltage by an over-current detector circuit, and this leads to protecting a circuit against the over-current. The over-current protection apparatus is characterized in that an external resistor is connected to one of the voltage-dividing resistors in series or in parallel so as to change a ratio of voltage division.

The Japanese Patent Laid-Open Publication No. 2003-319546 (referred to as a third patent document hereinafter) discloses a hybrid integrated circuit apparatus that enables a desired resistance value to be selected by switching in place of the use of the external resistance as disclosed in the second patent document.

In the semiconductor apparatus disclosed in first patent document, it is necessary to provide the current mirror circuit. In the apparatus disclosed in each of the second and third patent documents, the detected voltage is amplified by the amplifier, and an output voltage from the amplifier is adjusted by a voltage divider having a variable voltage-dividing resistance so as to adjust the detected voltage. As a result, a circuit configuration becomes disadvantageously complicated, and it is necessary for the circuit to be disadvantageously greatly changed.

### SUMMARY OF THE INVENTION

An essential object of the present invention is therefore to provide a semiconductor apparatus having a circuit configuration simpler than that of the conventional apparatus, being capable of easily changing the comparison reference voltage without any current circuit.

In order to achieve the aforementioned objective, according to one aspect of the present invention, there is provided a semiconductor apparatus including a power switching semiconductor device, a control integrated circuit, a current detector, and a protection circuit. The control integrated circuit drives the power switching semiconductor device, and the current detector section for detecting a current flowing in the power switching semiconductor device. The protection circuit compares a detected voltage obtained from the current detector section with a comparison reference voltage obtained from a predetermined reference voltage, and stops the control integrated circuit from driving the power switching semiconductor device when the detected voltage is higher than the comparison reference voltage. The semiconductor apparatus preferably further includes a terminal for pulling out a line of the comparison reference voltage to an external circuit of the semiconductor apparatus so as to change the comparison reference voltage by means of an external resistor connected to the terminal.

According to the present invention, the reference voltage is increased or reduced by connecting the external resistor to the terminal provided to pull out the line of the reference voltage to the external circuit of the semiconductor apparatus. Due to this, the trip level for the over-current protection can be easily changed, and it is unnecessary to greatly change the design of the semiconductor apparatus.

### BRIEF DESCRIPTION OF THE DRAWINGS

These and other objects and features of the present invention will become clear from the following description taken in conjunction with the preferred embodiments thereof with reference to the accompanying drawings throughout which like parts are designated by like reference numerals, and in which:

FIG. 1 is a circuit diagram of a power semiconductor apparatus according to a first preferred embodiment of the present invention;

FIG. 2 is a control block diagram showing details of a control integrated circuit shown in FIG. 1;

FIG. 3 is a circuit diagram of a power semiconductor apparatus according to a second preferred embodiment of the present invention;

FIG. 4 is a control block diagram showing details of a control integrated circuit shown in FIG. 3; and

FIG. 5 is a circuit diagram showing a connection relationship among IGBTs.

### DETAILED DESCRIPTION OF THE PREFERRED EMBODIMENTS

Preferred embodiments according to the present invention will be described below with reference to the attached drawings.

### First Preferred Embodiment

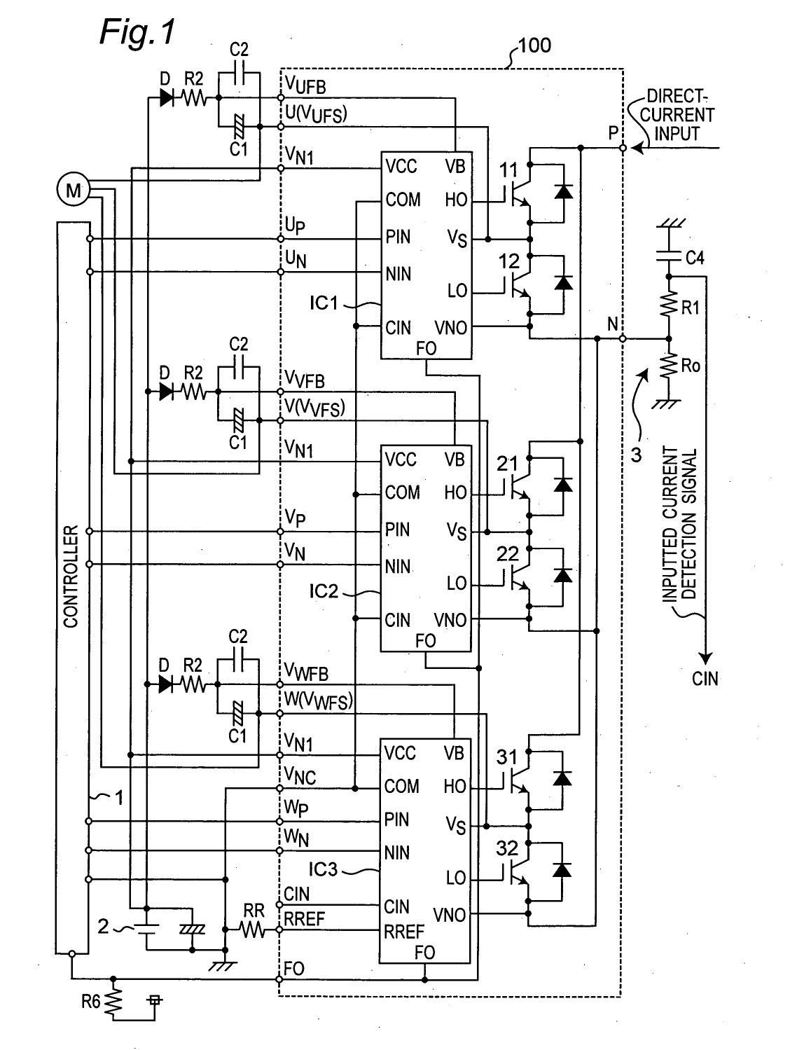

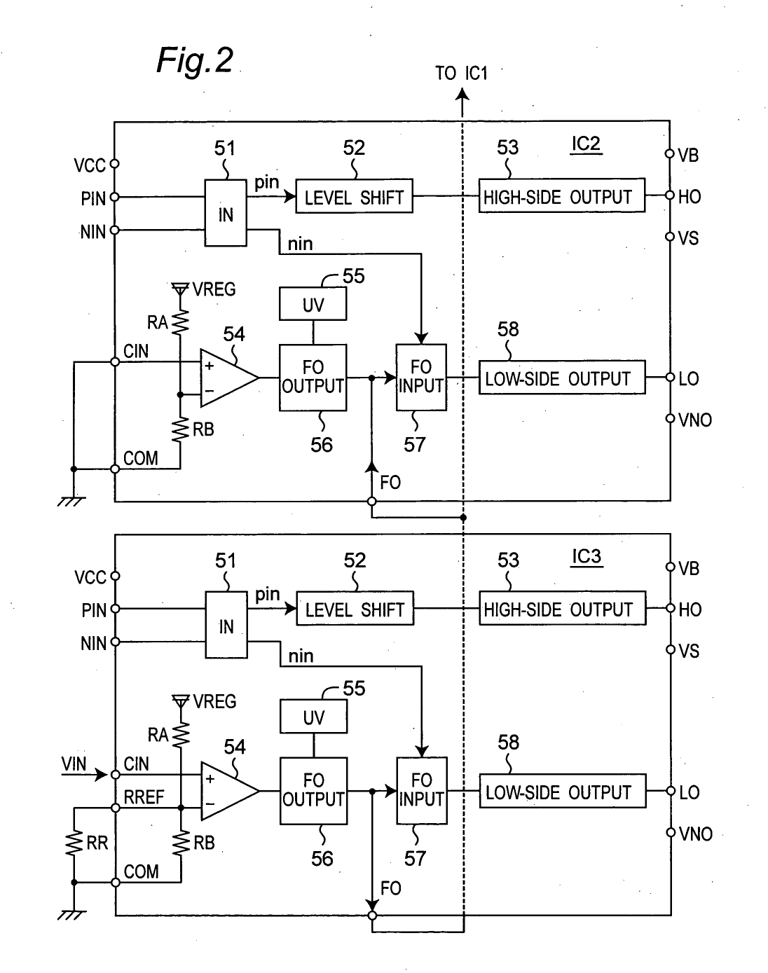

FIG. 1 is a circuit diagram of a power semiconductor apparatus 100 including six IGBTs (11, 12, 21, 22, 31 and 32) and three control integrated circuits (IC1 to IC3) that controls switching of these IGBTs. A system thereof includes a controller 1 that controls the power semiconductor apparatus 100, a power supply 2 that supplies an electric power to the power semiconductor apparatus 100, and an inputted current detector circuit 3 that is constituted by a shunt resistor R₀, a resistor R1, and a capacitor C4. FIG. 2 is a control block diagram of the control integrated circuits IC2 and IC3.

Referring to FIG. 1, paired IGBTs (11, 12), (21, 22), and (31, 32), each being connected in a form of a totem-pole connection, are connected in parallel between terminals P and N through which a direct-current input voltage is supplied to the power semiconductor apparatus 100. In FIG. 1, the IGBTs are arranged on a line longitudinally to correspond to an actual arrangement of the IGBTs in a package. As shown in FIG. 5, these six IGBTs constitute a three-phase bridge circuit which has been known to those skilled in the art.

A connection point at each of the paired IGBTs (11, 12), (21, 22), and (31, 32) is connected to a terminal Vs of the corresponding control integrated circuit (IC), and is also connected to output terminals U(VUFS), V(VVFS), and W(VWFS) of the power semiconductor apparatus 100. A load such as a three-phase motor M or the like is connected to these output terminals.

The terminal N is grounded through the shunt resistor R₀ having a low resistance value, and is also grounded through a serial circuit which includes the resistor R1 and the capacitor C4. An inputted current detection signal that indicates a magnitude of an inputted current is pulled out from a connection point between the resistor R1 and the capacitor C4, and then, is supplied to a terminal CIN of one control integrated circuit (IC3 in the present preferred embodiment) among the control integrated circuits (IC1 to IC3).

The controller 1 supplies a predetermined control signal to the respective control integrated circuits (IC1 to IC3) in the power semiconductor apparatus 100 through various kinds of terminals so as to control the control integrated circuits (IC1 to IC3). A direct-current voltage of 15V is supplied from the power supply 2 to a power supply terminal VCC of each of the control integrated circuits (IC1 to IC3).

Further, the direct-current voltage from the power supply 2 is also supplied to a terminal VB of each of the control integrated circuits (IC1 to IC3) through a diode D and a resistor R2. It is noted that capacitors C1 and C2 each of a capacitance of about 0.1 to 2 μF which is connected between one end of the resistor R2 and each output terminal are provided for noise elimination, where the capacitors C1 and C2 having good temperature characteristics are employed.

A high-side output terminal HO of the control integrated circuit IC3 is connected to a gate of the high-side IGBT 31, whereas a low-side output terminal LO is connected to a gate of the low-side IGBT 32. The other control integrated circuits IC1 and IC2 are constituted in a manner similar to that of the control integrated circuit IC3. Accordingly, a one-phase circuit configuration constituted by the IC3 and the IGBTs 31 and 32 will be mainly described hereinafter.

As shown in FIG. 2, signals “pin” and “nin” inputted respectively through the terminals PIN and NIN of the control integrated circuit IC3 are subjected to a predetermined processing by an input section 51. Thereafter, the level of the signal “pin” is shifted to a high side by a level shift circuit 52, and the high-side IGBT 31 is driven in response to a driving signal from a high-side output section 53. On the other hand, the signal “nin” is inputted to a low-side output section 58 through an F0 input section 57, and the low-side IGBT 32 is driven in response to a driving signal from this low-side output section 58.

On the other hand, the inputted current detection signal as inputted through the terminal CIN is inputted as a detected voltage VIN, to one non-inversion input terminal (+) of a comparator 54 in the control integrated circuit IC3. A comparison reference voltage (VREF) having an internal reference voltage VREG obtained by a voltage-dividing circuit as constituted by resistors RA and RB is inputted to another inversion input terminal (−) of a reference input terminal of the comparator 54. Further, the control integrated circuit IC3 further includes a line of the comparison reference voltage VREF, namely, a terminal RREF for pulling out the reference input terminal (−) of the comparator 54 to the external circuit, and an external resistor RR is connected between the terminal RREF and the ground. In this case, this leads to that the external resistor RR is connected to the resistor RB in parallel.

When the resistor RR is not connected to the resistor RB, the comparison reference voltage VREF is expressed by the following Equation:
VREF=VREG·RB/(RA+RB) (1).

On the other hand, when the resistor RR is connected to the resistor RB, the comparison reference voltage VREF is lowered.

Further, in the case of (the detected voltage VIN)>(the comparison reference voltage VREF), a “High” signal is outputted from the comparator 54. In addition, when the level of the power supply is further reduced to be equal to or lower than a specified value, a “High” signal is also outputted from a low voltage detector section (UV) 55. When the “High” signal is inputted from the comparator 54 or the low voltage detector section 55 to an F0 output section 56, the F0 output section 56 outputs a “Low” fault signal F0.

The fault signal F0 is inputted to an F0 input section 57, and is also supplied from a terminal FO to the F0 input sections 57 of the other control integrated circuits IC1 and IC2 through an F0 signal supply line. As shown in FIG. 1, the F0 signal supply line, which is pulled up to the “High” level by a pull-up resistor R6, is switched over to a “Low” level in response to an output of the fault signal F0.

When fetching the fault signal F0, the F0 input section 57 outputs a “Low” signal to the low-side output section 58, and this leads to that the output of the driving signal from the low-side output section 58 is stopped in all the control integrated circuits. As a result, all of the low-side (lower-arm) IGBTs 12, 22 and 32 are turned off, and then, supply of the electric power to the load M is shut off. Thus, each of the control integrated circuits (IC1 to IC3) includes a protection circuit that is constituted by the comparator 54, the low voltage detector section (UV) 55, the F0 output section 56 and the F0 input section 57. Such a protection circuit is normally included in each of the control integrated circuits (IC1 to IC3). Alternatively, the protection circuit may be provided separately from the control integrated circuit.

As described above, since connecting of the external resistor RR can reduce the comparison reference voltage VREF, the trip level for the over-current protection can be reduced, and then, this leads to satisfying the design of the semiconductor apparatus in which a higher priority is given to a reduction in heat loss from the shunt resistor. In addition, any comparator 54 is not especially required in the control integrated circuits IC1 and IC2. However, if it is provided, the terminal CIN to be connected to the non-inversion input terminal (−) of the comparison input section is grounded so that it does not operate.

### Second Preferred Embodiment

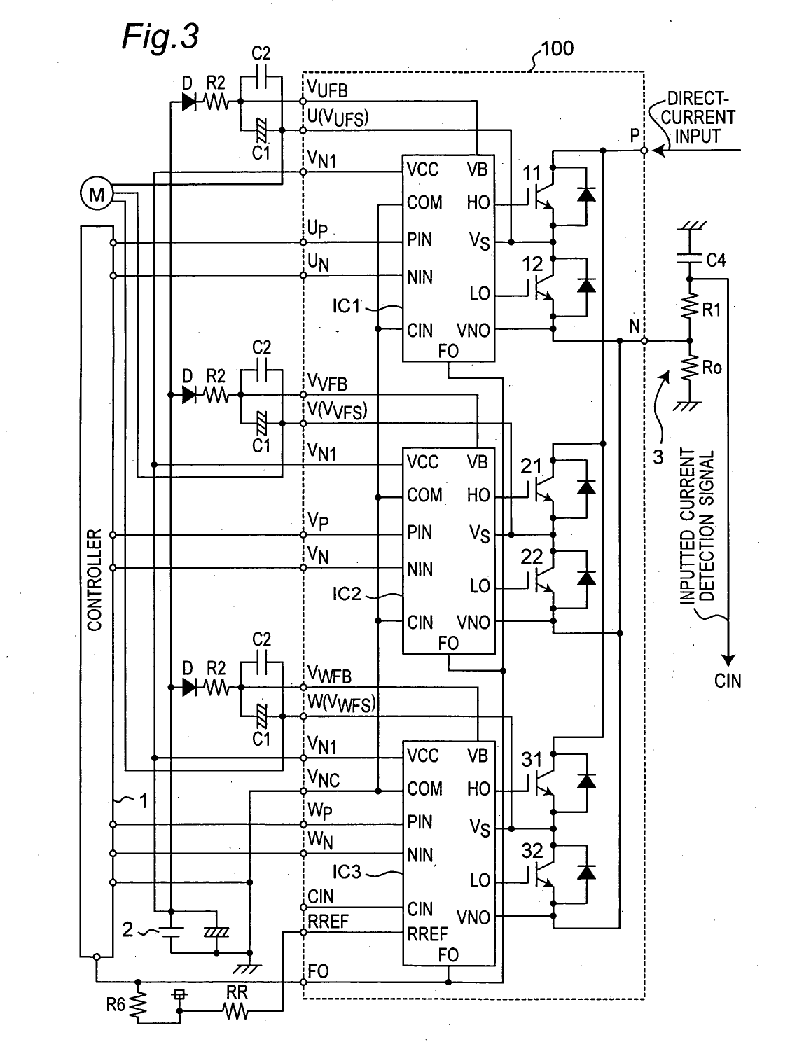

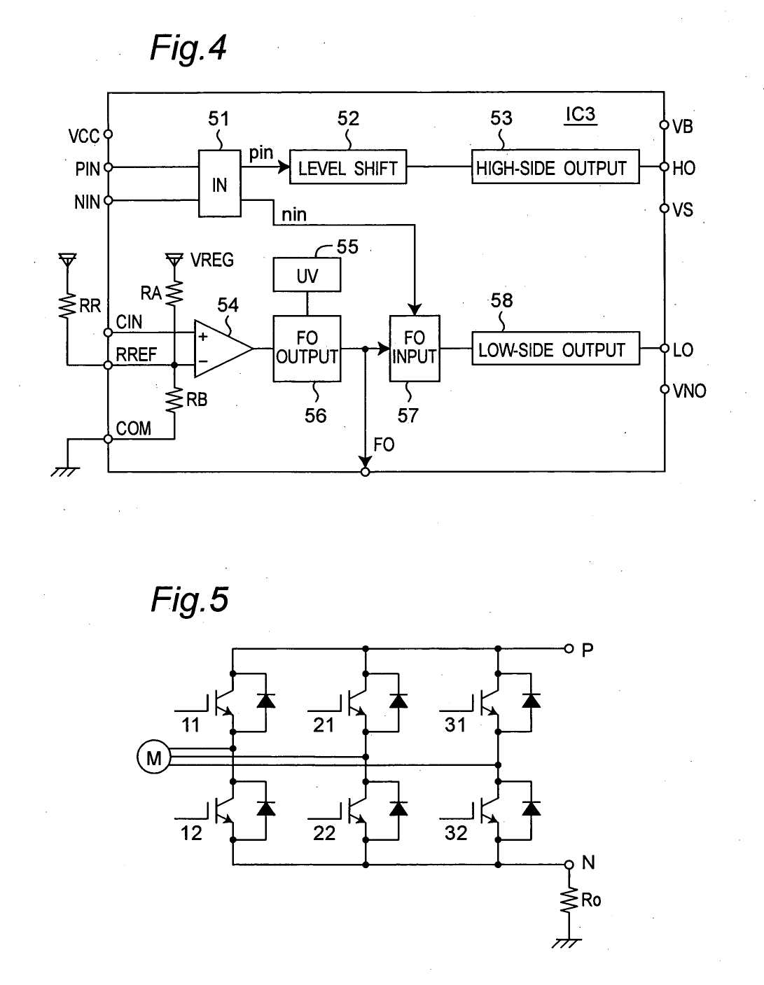

FIGS. 3 and 4 show a second preferred embodiment of the present invention. In FIG. 2, one end of the resistor RR is grounded, and this leads to connecting of the resistor RR to the resistor RB in parallel. Referring to FIG. 4, by contrast, one end of the external resistor RR is connected to an internal reference voltage. In this case, the external resistor RR is connected to the resistor RA in parallel. As shown in FIG. 4, when the external resistor RR is connected to the reference voltage of the comparator 54 to which the external resistor RR is not connected, the reference voltage rises. Accordingly, the trip level for the over-current protection can be changed toward upward, and this leads to satisfying the design of the semiconductor apparatus in which a higher priority is given to improvement in the precision of the over-current protection.

As can be understood from comparison of the control integrated circuit IC3 with the control integrated circuit IC2 equal in type to the conventional control integrated circuit with reference to FIG. 2, the semiconductor apparatus according to the present invention includes only the terminal RREF for pulling out the reference input terminal of the comparator 54 to the external circuit. Accordingly, the trip level for the over-current protection can be adjusted without changing any internal circuit configuration of the control integrated circuit, and this leads to that improvement in the precision of the over-current protection.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

What is claimed is:

1. A semiconductor apparatus comprising:
a power switching semiconductor device;
a control integrated circuit for driving said power switching semiconductor device;
a current detector section for detecting a current flowing in said power switching semiconductor device; and
a protection circuit for comparing a detected voltage obtained from said current detector section with a comparison reference voltage obtained from a predetermined reference voltage, and for stopping said control integrated circuit from driving said power switching semiconductor device when the detected voltage is higher than the comparison reference voltage,
characterized in that
said semiconductor apparatus includes a terminal for pulling out a line of the comparison reference voltage to an external circuit of the semiconductor apparatus so as to change the comparison reference voltage by means of an external resistor connected to the terminal.

2. The semiconductor apparatus as claimed in claim 1,
wherein another end of the external resistor connected to the terminal is grounded.

3. The semiconductor apparatus as claimed in claim 1,
wherein another end of the external resistor connected to the terminal is connected to a reference voltage of the semiconductor apparatus.
